(19) United States
(12) Patent Application Publication
(10) Pub. No.: US 2016/0116522 A1
(43) Pub. Date: Apr. 28, 2016

(54) FULLY ADAPTIVE FAULT LOCATION METHOD

(71) Applicant: KING FAHD UNIVERSITY OF PETROLEUM AND MINERALS, DHAHRAN (SA)

(72) Inventors: MOHAMMAD ALI YOUSEF ABIDO, DHAHRAN (SA); ALI HASSAN AL-MOHAMMED, DAMMAM (SA)

(21) Appl. No.: 14/525,198

(22) Filed: Oct. 27, 2014

(51) Int. Cl. G01R 31/08

(52) U.S. Cl. CPC G01R 31/088; G01R 31/085

(57) ABSTRACT

The fully adaptive fault location method is based on synchronized phasor measurements obtained by Phasor Measurement Units (PMUs). The method utilizes only PMU synchronized measurements and does not require any data to be provided by the electric utility. Line parameters for each section of the line and Thevenin's equivalents (TEs) of the system at each of three terminals are determined online, utilizing three independent sets of pre-fault PMU measurements. This ensures that the actual operating conditions of the system are adequately considered. Simulation results show that the present method is capable of producing reliable and very accurate solutions.

### BACKGROUND OF THE INVENTION

1. Field of the Invention

The present invention relates to multi-terminal line fault location, and particularly to a fully adaptive fault location method for three-terminal lines based on synchronized phasor measurements.

2. Description of the Related Art

Multi-terminal lines are those having three or more terminals with substantial generation behind each. Based on the number of terminals we can distinguish three-terminal lines having three terminals, four-terminal lines having four terminals, and so on. Multi-terminal lines are used in power systems for economical or environmental-protection reasons.

Fault location has always been an important subject to power system engineers due to the fact that accurate and swift fault location on a power network can expedite repair of faulted components, speed-up power restoration and thus enhance power system reliability and availability. Rapid restoration of service could reduce customer complaints, outage time, loss of revenue, and crew repair expense.

Fault location on multi-terminal lines relies on identifying the line section at which the fault occurred and determining the distance to fault for the faulted section. PMUs (Phasor Measurement Units) have recently evolved into mature tools and are now being utilized in the field of fault location. Recognizing the importance of the fault location function for multi-terminal lines, several PMU-based fault location algorithms have been proposed in the literature. Yet, there remains a need for improving the fault location accuracy achieved by existing PMU-based fault location algorithms.

Thus, a fully adaptive fault location method solving the aforementioned problems is desired.

### SUMMARY OF THE INVENTION

The fully adaptive fault location method is based on synchronized phasor measurements obtained by Phasor Measurement Units (PMUs). The method utilizes only PMU synchronized measurements and does not require any data to be provided by the electric utility. Line parameters for each section of the line and Thevenin's equivalents (TEs) of the system at each of three terminals are determined online, utilizing three independent sets of pre-fault PMU measurements. This ensures that the actual operating conditions of the system are adequately considered. Simulation results show that the present method is capable of producing reliable and very accurate solutions.

These and other features of the present invention will become readily apparent upon further review of the following specification and drawings.

### BRIEF DESCRIPTION OF THE DRAWINGS

FIG. 1 is diagram showing a sinusoidal waveform and its corresponding phasor representation.

FIG. 2 is a schematic diagram showing a three-terminal transmission network.

FIG. 3 is a schematic diagram representing a steady-state pi equivalent circuit model of the three-terminal transmission network of FIG. 2.

FIG. 4 is a schematic diagram representing a faulted three-terminal system in pi equivalent model.

FIG. 5 is a flowchart representing steps in the fully adaptive fault location method according to the present invention.

FIG. 6 is a plot showing the effect of fault inception angle (FIA) on fault location (FL) accuracy (section A).

FIG. 7 is a plot showing the effect of FIA on FL accuracy (section B).

FIG. 8 is a plot showing the effect of FIA on FL accuracy (section C).

FIG. 9 is a plot showing the effect of parameter variation on FL accuracy.

Similar reference characters denote corresponding features consistently throughout the attached drawings.

### DETAILED DESCRIPTION OF THE PREFERRED EMBODIMENTS

It will be understood that the diagrams in the figures depicting the fully adaptive fault location method are exemplary only, and may be embodied in a dedicated electronic device having a microprocessor, microcontroller, digital signal processor, application specific integrated circuit, field programmable gate array, any combination of the aforementioned devices, or other device that combines the functionality of the fully adaptive fault location method onto a single chip or multiple chips programmed to carry out the method steps described herein, or may be embodied in a general purpose computer having the appropriate peripherals attached thereto and software stored on a computer readable media that can be loaded into main memory and executed by a processing unit to carry out the functionality of the method steps described herein.

The fully adaptive fault location method is applied to three-terminal lines and utilizes PMU (phase measurement unit) synchronized measurements, while not requiring any data to be provided by the electric utility. Line parameters for each section of the line and Thevenin's equivalents (TEs) of the system at each of the three terminals are determined online, utilizing three independent sets of pre-fault PMU measurements. The three sets of pre-fault PMU measurements at each terminal are used for online calculation of the respective TE.

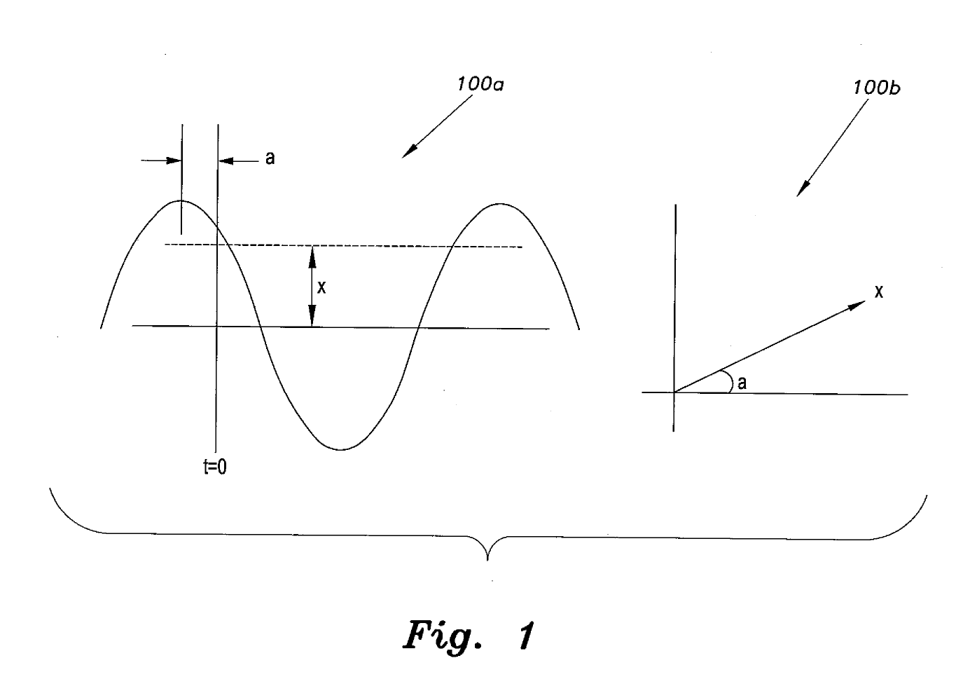

Consider the steady-state waveform 100a of a nominal power frequency signal, as shown in FIG. 1. If the waveform observation starts at the instant t=0, the steady-state waveform may be represented by a vector 100b comprising a complex number with a magnitude equal to the rms value of the signal at a phase angle equal to the angle α.

In a digital measuring system, samples of the waveform for one (nominal) period are collected, starting at t=0, and then the fundamental frequency component of the Discrete Fourier Transform (DFT) is calculated according to the relation:

$$X = \frac{\sqrt{2}}{N} {\sum }_{k = 1}^{N} {x}_{k} {e}^{- j2π k / N} \qquad ( 1 )$$

where N is the total number of samples in one period, X is the phasor, and xₖ is the waveform samples. This definition of the phasor has the merit that it uses a number of samples N of the waveform and is the correct representation of the fundamental frequency component when other transient components are present. Once the phasors (Xₐ, X_{b} and X_{c}) for the three phases are computed, positive, negative and zero sequence phasors are obtained using the following transformation.

$$[ \begin{matrix}{X}_{1} \\ {X}_{2} \\ {X}_{0}\end{matrix} ] = \frac{1}{3} [ \begin{matrix}1 & {e}^{j2π / 3} & {e}^{j4π / 3} \\ 1 & {e}^{j4π / 3} & {e}^{j2π / 3} \\ 1 & 1 & 1\end{matrix} ] \cdot [ \begin{matrix}{X}_{a} \\ {X}_{b} \\ {X}_{c}\end{matrix} ] \qquad ( 2 )$$

When several voltages and currents in a power system are measured and converted to phasors in this fashion, they are on a common reference if they are sampled at precisely the same instant. This is easy to achieve in a substation, where the common sampling clock pulses can be distributed to all the measuring systems. However, to measure common-reference phasors in substations separated from each other by long distances, the task of synchronizing the sampling clocks is not a trivial one. Only with the advent of the Global Positioning System (GPS) satellite transmissions, the PMU technology has now reached a stage whereby we can synchronize the sampling processes in distant substations economically and with an error of less than 1 μs. This error corresponds to 0.021° for a 60 Hz system and 0.018° for a 50 Hz system, and is certainly more accurate than any presently conceived application would demand.

With respect to online Thevenin's equivalent using local PMU measurements, one aspect of adaptive fault location is concerned with online determination of system TEs at the terminals of the line under study. Among their various potential applications in power systems, PMUs can be utilized for such purpose. This is possible with PMUs, since voltage and current phasors are provided at high rates of one measurement per cycle, but is not possible with the conventional SCADA systems that are too slow. Three consecutive voltage and current (V,I) measurements are used to determine an exact TE at the two line terminals. It is required that the three sets of phasor measurements be referred to the same reference. From the first and second sets of voltage and current measurements, the following equation can be written:

$${( r + \frac{{P}_{1} - {P}_{2}}{{I}_{1}^{2} - {I}_{2}^{2}} )}^{2} + {( x - \frac{{Q}_{1} - {Q}_{2}}{{I}_{1}^{2} - {I}_{2}^{2}} )}^{2} = \frac{{V}_{2}^{2} - {V}_{1}^{2}}{{I}_{1}^{2} - {I}_{2}^{2}} + {( \frac{{P}_{1} - {P}_{2}}{{I}_{1}^{2} - {I}_{2}^{2}} )}^{2} + {( \frac{{Q}_{1} - {Q}_{2}}{{I}_{1}^{2} - {I}_{2}^{2}} )}^{2} \qquad ( 3 )$$

where r and x are the resistance and the reactance of the Thevenin impedance (Zₜₕ). In equation (3), P and Q are the real and reactive powers. Equation (3) represents a circle in the impedance plane defining the locus for Zₜₕ that satisfies the two measurements, but it does not define a specific value for Zₜₕ. Therefore, a third measurement is required, which can be used with either the first or the second measurement in the same way to produce another circle. Among the two intersection points of the two circles, a selection criterion is applied to determine the equivalent impedance Zₜₕ. The equivalent Thevenin voltage (Eₜₕ) at a node is found knowing Zₜₕ and the local V and I measurements at that node, as shown in equation (4):

V=Eₜₕ+Zₜₕ·I. (4)

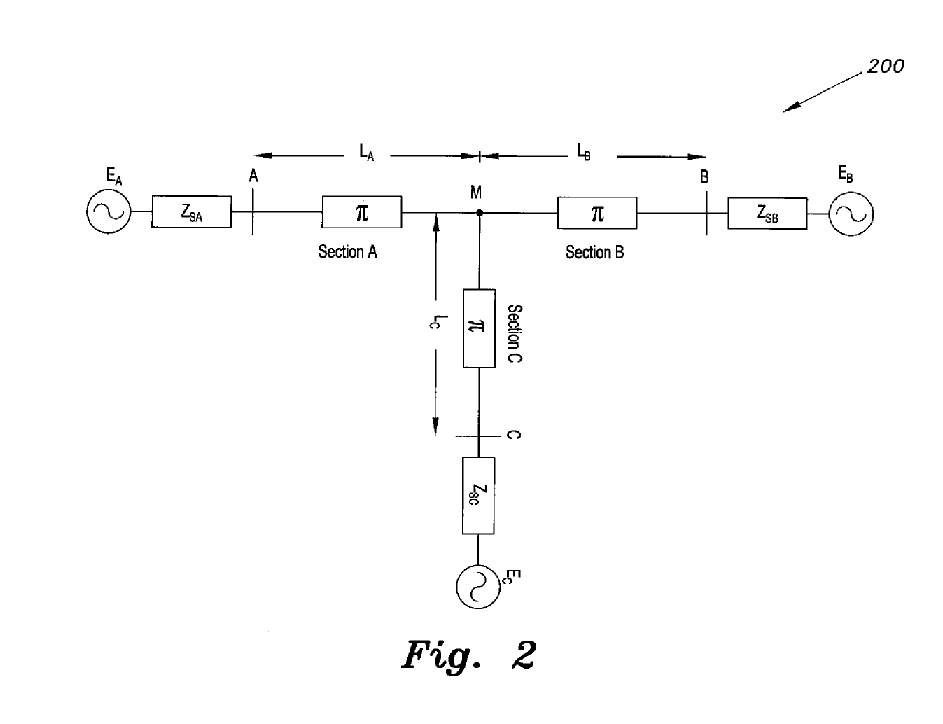

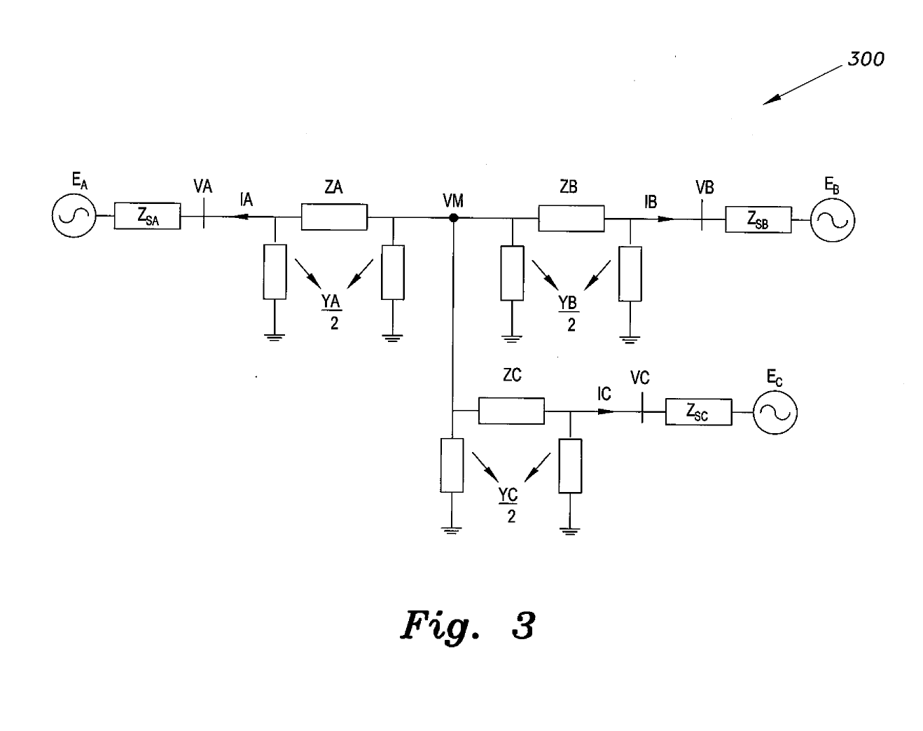

Regarding estimation of three-terminal line parameters using PMU measurements, the equivalent x model of a three-terminal transmission network and its corresponding steady-state representation are as shown in diagrams 200 and 300 of FIGS. 2 and 3, respectively. The parameters illustrated in the diagrams are defined in Table 1.

TABLE 1
Parameters of the Three-Terminal Transmission Network

| Parameter | Interpretation |
|---|---|
| E_{A}, Z_{SA} | Thevenin's equivalent at terminal A |
| E_{B}, Z_{SB} | Thevenin's equivalent at terminal B |
| E_{C}, Z_{SC} | Thevenin's equivalent at terminal C |
| VA, IA | Voltage and current at terminal A |
| VB, IB | Voltage and current at terminal B |
| VC, IC | Voltage and current at terminal C |
| L_{A} | Length of section A |
| L_{B} | Length of section B |
| L_{C} | Length of section C |
| ZA, YA | Impedance, admittance of section A |
| ZB, YB | Impedance, admittance of section B |
| ZC, YC | Impedance, admittance of section C |
| VM | Voltage at node M |

For the first set of measurements, the following equations can be written for section A, B and C:

(VM)₁−ZA*(IA)₁−0.5*(VA)₁*ZA*YA−(VA)₁=0 (5)

(VM)₁−ZB*(IB)₁−0.5*(VB)X*ZB*YB−(VB)₁=0 (6)

(VM)₁−ZC*(IC)₁−0.5*(VC)₁*ZC*YC−(VC)₁=0 (7)

The subscript (1) is used in equations (5)-(7) to denote the first set of measurements. Using the subscript (2) and (3) to denote respectively the second and the third sets of measurements, we write the following equations:

(VM)₂−ZA*(IA)₂−0.5*(VA)₂*ZA*YA−(VA)₂=0 (8)

(VM)₂−ZB*(IB)₂−0.5*(VB)₂*ZB*YB−(VB)₂=0 (9)

(VM)₂−ZC*(IC)₂−0.5*(VC)₂*ZC*YC−(VC)₂=0 (10)

(VM)₃−ZA*(IA)₃−0.5*(VA)₃*ZA*YA−(VA)₃=0 (11)

(VM)₃−ZB*(IB)₃−0.5*(VB)₃*ZB*YB−(VB)₃=0 (12)

(VM)₃−ZC*(IC)₃−0.5*(VC)₃*ZC*YC−(VC)₃=0 (13)

Equation (5) is a complex equation that can be written into two real nonlinear equations, as shown below:

$$\begin{matrix}Re [ {( VM )}_{1} ] - Re [ ZA ] * Re [ {( IA )}_{1} ] + Im [ ZA ] * Im [ {( IA )}_{1} ] + 0.5 * Re [ {( VA )}_{1} ] * Im [ ZA ] * Im [ YA ] + 0.5 * Im [ {( VA )}_{1} ] * Im [ YA ] * Re [ ZA ] - Re [ {( VA )}_{1} ] = 0 & ( 14 ) \\ Im [ {( VM )}_{1} ] - Re [ ZA ] * Im [ {( IA )}_{1} ] - Im [ ZA ] * Re [ {( IA )}_{1} ] - 0.5 * Re [ {( VA )}_{1} ] * Im [ YA ] * Re [ Z A ] + 0.5 * Im [ {( VA )}_{1} ] * Im [ ZA ] * Im [ YA ] - Im [ {( VA )}_{1} ] = 0 & ( 15 )\end{matrix}$$

Proceeding in the same manner for (6)-(13), an additional sixteen equations can be written to have a total of eighteen equations and fifteen unknowns to solve for, namely, Re[ZA], Im[ZA], Im[YA], Re[ZB], Im[ZB], Im[YB], Re[ZC], Im[ZC], Im[YC], Re[(VM)₁], Im[(VM)₁], Re[(VM)₂], Im[(VM)₂], Re[(VM)₃], and Im[(VM)₃]. The classical least squares based method can be applied to obtain a more robust estimate of the unknowns.

With respect to the present adaptive fault location method, in steady state, the voltage of node M in FIG. 3 can be calculated in terms of the voltage of bus A or B or C as:

$$\begin{matrix}VM = ( {I}_{3 \times 3} + ZA ( YSA + \frac{YA}{2} ) ) Δ V A & ( 16 ) \\ VM = ( {I}_{3 \times 3} + ZB ( YSB + \frac{YB}{2} ) ) Δ VB & ( 17 ) \\ VM = ( {I}_{3 \times 3} + ZC ( YSC + \frac{YC}{2} ) ) Δ VC & ( 18 )\end{matrix}$$

The voltage parameters of node M in the block diagram 300 of FIG. 3 are defined in Table 2.

TABLE 2
Parameters of Node M

| Parameter | Interpretation |
|---|---|
| ΔVA | Superimposed voltage at terminal A |
| ΔVB | Superimposed voltage at terminal B |
| ΔVC | Superimposed voltage at terminal C |
| YSA | Thevenin admittance at terminal A |
| YSB | Thevenin admittance at terminal B |
| YSC | Thevenin admittance at terminal C |
| I | Unit matrix |

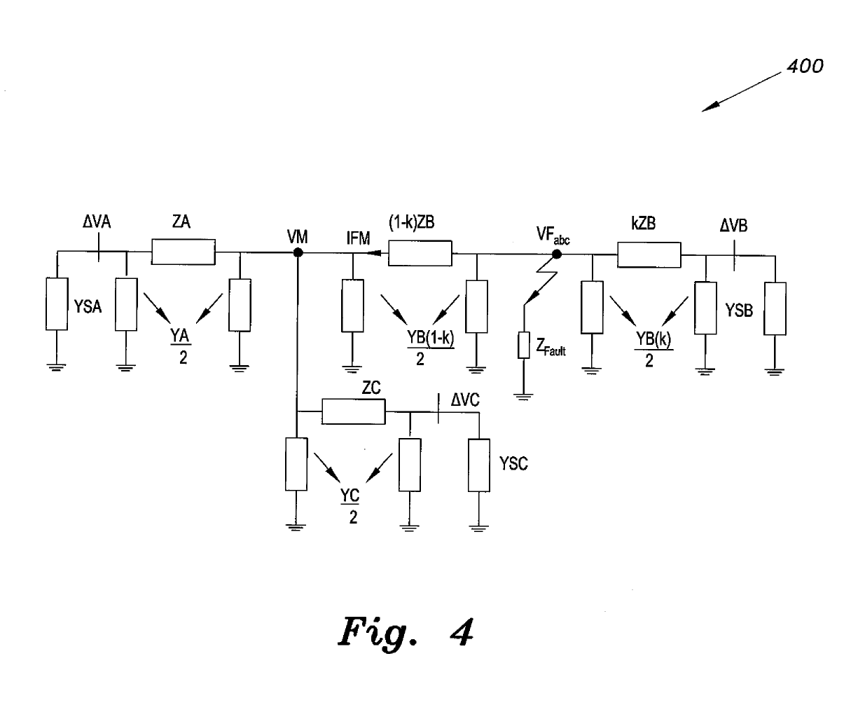

Considering an unknown fault has occurred in section B with the distance of l₁ from bus B, the Thevenin's model of the faulted system is shown in diagram 400 in FIG. 4. The faulted point voltage can be written as:

VF=VM+ZB(1−k)IFM (19)

Also, for the faulted section, the following equations can be written to obtain its bus voltage:

$$VF = Δ VB [ 1 + ZBk ( YSB + \frac{YB}{2} k ) ] \qquad ( 20 )$$

Equating (19) and (20) and after expressing VM and IFM in terms of terminal voltages and line parameters, we obtain k as:

k=f(ΔVA,ΔVB,ΔVC)→ak²+bk+c=0, (21)

such that:

$$a = ZB \frac{YB}{2} Δ VB + ZB \frac{YA}{2} Δ V A + ZB \frac{YC}{2} Δ VC \\ b = ZBYSB Δ VB - ZB \frac{YA}{2} Δ V A - ZB \frac{YC}{2} Δ VC + ZB \frac{YB}{2} VM + ZBYSA Δ V A + ZBYSC Δ VC + ZB ( \frac{YA}{2} + \frac{YB}{2} + \frac{YC}{2} ) VM \\ c = Δ VB - VM - ZBYSA Δ V A - ZBYSC Δ VC - ZB ( \frac{YA}{2} + \frac{YB}{2} + \frac{YC}{2} ) VM , \qquad ( 22 )$$

and VM is obtained using either (16) or (18). The estimated fault point distance can be calculated as:

l_{1B}=k×L_{B} (23)

If we consider that an unknown fault is occurred in section A with the distance of l₁ from bus A, then the quadratic equation coefficients a, b and c are given as:

$$a = ZA \frac{YA}{2} Δ V A + ZA \frac{YB}{2} Δ VB + ZA \frac{YC}{2} Δ VC \\ b = ZAYSA Δ V A - ZA \frac{YB}{2} Δ VB - ZA \frac{YC}{2} Δ VC + ZA \frac{YA}{2} VM + ZAYSB Δ VB + ZAYSC Δ VC + ZA ( \frac{YA}{2} + \frac{YB}{2} + \frac{YC}{2} ) VM \\ c = Δ V A - VM - ZAYSB Δ VB - ZAYSC Δ VC - ZA ( \frac{YA}{2} + \frac{YB}{2} + \frac{YC}{2} ) VM , \qquad ( 24 )$$

and VM is obtained using either (17) or (18). The estimated fault point distance can be calculated:

l_{1A}=k×L_{A} (25)

Finally, if we consider that an unknown fault is occurred in section C with the distance of 1 from bus C, then the quadratic equation coefficients a, b and c are given as:

$$a = ZC \frac{YC}{2} Δ VC + ZC \frac{YA}{2} Δ V A + ZC \frac{YB}{2} Δ VB \\ b = ZCYSC Δ VC - ZC \frac{YA}{2} Δ V A - ZC \frac{YB}{2} Δ VB + ZC \frac{YC}{2} VM + ZCYSA Δ V A + ZCYSB Δ VB + ZC ( \frac{YA}{2 } + \frac{YB}{2} + \frac{YC}{2} ) VM \\ c = Δ VC - VM - ZCYSA Δ V A - ZCYSB Δ VB - ZC ( \frac{YA}{2} + \frac{YB}{2} + \frac{YC}{2} ) VM , \qquad ( 26 )$$

and VM is obtained using either (16) or (17). The estimated fault point distance can be calculated:

l_{1C}=k×L_{C}. (27)

FIG. 5 is a flowchart highlighting the main steps 500 of the present adaptive fault location method for a three-terminal line. The method of multiple measurements using linear regression (MMLR) is used for calculation of line parameters, since it is more immune to random noise and bias errors that may exist in voltage and current measurements. According to the present fully adaptive fault location method, at step 502a, three independent sets of PMU pre-fault voltage and current phasor measurements and one set of post-fault voltage phasor measurements are taken at a first terminal (A). At step 502b, three independent sets of PMU pre-fault voltage and current phasor measurements and one set of post-fault voltage phasor measurements are taken at a second terminal (B). At step 502c, three independent sets of PMU pre-fault voltage and current phasor measurements and one set of post-fault voltage phasor measurements are taken at a third terminal (C). At step 504, the present method performs an online determination of the power transmission network's Thevenin's Equivalents at terminals A, B and C from pre-fault measurements. At step 506, the present method performs an online calculation of impedance and admittance line parameters for sections A, B and C from pre-fault measurements using the method of MMLR. At step 508, the present method performs an extraction of superimposed electrical voltage measurements using the most recent set of pre-fault measurements and the set of post-fault measurements. Step 510 performs the symmetrical transformation to obtain the positive, negative, and zero sequence phasors. At step 512, the faulted section is identified, and at step 514, the fault location is determined.

With respect to simulation results, we consider a 500 kV three-terminal network, as depicted in the schematic diagram 200 of FIG. 2. Various types of faults on sections A, B, and C are studied. The three-terminal line is modeled in PSCAD/EMTDC with its distributed parameters. Table 1 shows the simulation parameters, where the system's TEs at terminals A, B, and C are determined. The CTs and VTs located at each line terminal are assumed as ideal devices. The three-phase voltage and current signals are sampled at a frequency of 240 Hz, which corresponds to 4 samples per cycle, and are stored for post-processing. Sections A, B, and C are assumed to have the same impedance and admittance per unit length. The DFT given by equation (1) is applied to extract the voltage and current phasors. The present method can be implemented in MATLAB or any other computer program having a collection of mathematical library routines. The percentage error used to measure the accuracy of fault location algorithm is as expressed as:

$$\% Error = \frac{\vert Actual location - Estimated location \vert}{Total line length} \times 100 \qquad ( 28 )$$

The Thevenin's equivalent voltages calculated are shown in Table 3.

TABLE 3
Parameters of the 500 kV Three-Terminal Network

| Parameter | Value | |
|---|---|---|
| L_{A} | 150 | mile |
| L_{B} | 100 | mile |
| L_{C} | 110 | mile |
| R | 0.249168 | Ω/mile |
| L | 1.556277 | mH/mile |
| C | 19.469e−9 | F/mile |

| | |
|---|---|
| E_{A} | 500 kV ∠0° |
| E_{B} | 475 kV ∠ −15° |
| E_{C} | 472 kV ∠ −10° |
| Z_{SA} | 5.7257 + j15.1762 Ω |
| Z_{SB} | 5.1033 + j15.3082 Ω |
| Z_{SC} | 5.4145 + j15.2422 Ω |

With respect to influence of the fault type and fault location, to test the accuracy of the present method, different type of faults with different fault locations have been simulated on section A, B and C. Tables 4-7 present the fault location estimates obtained for the single line to ground (LG) faults, line to line (LL) faults, three phase (LLL) faults and line to line to ground (LLG) faults) on section A, B and C. From the results obtained, it is observed that the proposed algorithm is reasonably accurate and virtually independent of the fault type and fault location.

Regarding the influence of fault resistance, the effect of the fault resistance variation on the algorithm's accuracy for all types of faults is shown in Tables 8-11, respectively, assuming that the fault occurs at a distance of 0.4 p.u. (phase units) from terminals A, B, and C, respectively. Faults involving ground have been investigated for fault resistance values varying from 0 to 250Ω. This captures low- and high-resistance faults. Faults not involving ground have been investigated for resistance values ranging between 0 to 30Ω. Referring to the aforementioned tables, it can be easily seen that the fault location estimates are reasonably accurate and virtually independent of the fault resistance.

TABLE 4
Fault Location Estimates for LG Faults

| | Fault | | Error of Estimated FL | | |
|---|---|---|---|---|---|
| Fault | Res. | Actual FL | (%) on section | | |
| Type | (Ω) | (p.u.) | A | B | C |
| AG | 10 | 0.2 | 0.4838 | 0.1781 | 0.4191 |
| | | 0.4 | 0.2422 | 0.4770 | 0.9031 |
| | | 0.6 | 0.6464 | 0.9370 | 1.7763 |
| | | 0.8 | 1.0525 | 1.1834 | 1.8204 |
| | 100 | 0.2 | 0.3516 | 1.2626 | 1.3470 |
| | | 0.4 | 0.4333 | 0.1619 | 1.2761 |
| | | 0.6 | 1.0650 | 1.0189 | 3.4265 |
| | | 0.8 | 1.4361 | 1.3546 | 2.7243 |
| BG | 10 | 0.2 | 0.0909 | 0.2153 | 0.7681 |
| | | 0.4 | 0.4519 | 0.9337 | 1.1168 |
| | | 0.6 | 0.7907 | 0.8831 | 2.1249 |
| | | 0.8 | 1.1050 | 1.4224 | 1.7628 |
| | 100 | 0.2 | 0.7626 | 1.0763 | 2.6231 |
| | | 0.4 | 1.2449 | 1.7611 | 2.2581 |
| | | 0.6 | 1.2493 | 1.8000 | 3.6661 |
| | | 0.8 | 1.4111 | 1.8744 | 2.7667 |
| CG | 10 | 0.2 | 0.2918 | 0.5297 | 0.7319 |
| | | 0.4 | 0.5749 | 1.4190 | 1.4722 |
| | | 0.6 | 0.5667 | 0.8838 | 2.0622 |
| | | 0.8 | 1.0704 | 1.3595 | 1.7426 |
| | 100 | 0.2 | 0.4433 | 0.1895 | 1.4520 |
| | | 0.4 | 0.7069 | 1.3343 | 1.8373 |
| | | 0.6 | 0.9943 | 1.4118 | 3.1814 |
| | | 0.8 | 1.3706 | 1.5071 | 2.5472 |

TABLE 5
Fault Location Estimates for LL Faults

| | Fault | | Error of Estimated FL | | |
|---|---|---|---|---|---|
| Fault | Res. | Actual FL | (%) on section | | |
| Type | (Ω) | (p.u.) | A | B | C |
| AB | 1 | 0.2 | 0.3054 | 0.1119 | 0.3727 |
| | | 0.4 | 0.2091 | 0.3339 | 0.6850 |
| | | 0.6 | 0.6933 | 0.8495 | 1.4593 |
| | | 0.8 | 1.0358 | 1.2263 | 1.5706 |
| | 10 | 0.2 | 0.3241 | 0.1334 | 0.3815 |
| | | 0.4 | 0.2185 | 0.3811 | 0.7131 |
| | | 0.6 | 0.6996 | 0.8535 | 1.5363 |
| | | 0.8 | 1.0413 | 1.2376 | 1.6036 |
| BC | 1 | 0.2 | 0.0733 | 0.4636 | 0.6895 |
| | | 0.4 | 0.5069 | 1.2180 | 1.1712 |
| | | 0.6 | 0.6299 | 0.6831 | 1.8366 |
| | | 0.8 | 1.0820 | 1.4180 | 1.4838 |
| | 10 | 0.2 | 0.1145 | 0.5054 | 0.6952 |
| | | 0.4 | 0.5329 | 1.2981 | 1.2445 |
| | | 0.6 | 0.6268 | 0.7471 | 1.8694 |
| | | 0.8 | 1.0720 | 1.4213 | 1.5229 |
| CA | 1 | 0.2 | 0.4180 | 0.3157 | 0.4480 |
| | | 0.4 | 0.3839 | 1.0453 | 1.1509 |
| | | 0.6 | 0.4462 | 0.8313 | 1.5232 |
| | | 0.8 | 1.0038 | 1.2118 | 1.5684 |
| | 10 | 0.2 | 0.4771 | 0.2435 | 0.4058 |
| | | 0.4 | 0.3708 | 0.9826 | 1.1299 |
| | | 0.6 | 0.4642 | 0.8509 | 1.5349 |
| | | 0.8 | 1.0073 | 1.1996 | 1.5933 |

TABLE 6
Fault Location Estimates for LLLFaults

| | Fault | | Error of Estimated FL | | |
|---|---|---|---|---|---|
| Fault | Res. | Actual FL | (%) on section | | |
| Type | (Ω) | (p.u.) | A | B | C |
| ABC | 1 | 0.2 | 0.2774 | 0.2201 | 0.4328 |
| | | 0.4 | 0.3548 | 0.8354 | 0.9329 |
| | | 0.6 | 0.5524 | 0.7503 | 1.3816 |
| | | 0.8 | 1.0243 | 1.2631 | 1.4144 |
| | 10 | 0.2 | 0.3952 | 0.1885 | 0.3415 |
| | | 0.4 | 0.3432 | 0.8674 | 0.9484 |
| | | 0.6 | 0.5451 | 0.7918 | 1.3927 |
| | | 0.8 | 1.0098 | 1.2558 | 1.4392 |

TABLE 7
Fault Location Estimates for LLG Faults

| | Fault | | Error of Estimated FL | | |
|---|---|---|---|---|---|
| Fault | Res. | Actual FL | (%) on section | | |
| Type | (Ω) | (p.u.) | A | B | C |
| ABG | 5 | 0.2 | 0.2884 | 0.0619 | 0.4144 |
| | | 0.4 | 0.2847 | 0.5732 | 0.8079 |
| | | 0.6 | 0.6370 | 0.8197 | 1.4228 |
| | | 0.8 | 1.0291 | 1.2497 | 1.4998 |
| | 50 | 0.2 | 0.1997 | 0.1536 | 0.5274 |
| | | 0.4 | 0.3036 | 0.5427 | 0.8145 |
| | | 0.6 | 0.7003 | 0.9332 | 1.4576 |
| | | 0.8 | 1.0307 | 1.2809 | 1.5526 |
| BCG | 5 | 0.2 | 0.1738 | 0.3769 | 0.5838 |
| | | 0.4 | 0.4393 | 1.0722 | 1.0746 |
| | | 0.6 | 0.5899 | 0.7080 | 1.6417 |
| | | 0.8 | 1.0581 | 1.3477 | 1.4517 |
| | 50 | 0.2 | 0.0652 | 0.5591 | 0.7475 |
| | | 0.4 | 0.5112 | 1.2651 | 1.2039 |
| | | 0.6 | 0.6125 | 0.7152 | 1.7967 |
| | | 0.8 | 1.0753 | 1.4101 | 1.4749 |
| CAG | 5 | 0.2 | 0.3622 | 0.2789 | 0.4482 |
| | | 0.4 | 0.3727 | 0.9573 | 1.0644 |
| | | 0.6 | 0.4917 | 0.8156 | 1.4611 |
| | | 0.8 | 1.0082 | 1.2330 | 1.5106 |
| | 50 | 0.2 | 0.2955 | 0.4699 | 0.5967 |
| | | 0.4 | 0.4469 | 1.1084 | 1.2122 |
| | | 0.6 | 0.4790 | 0.9085 | 1.5314 |
| | | 0.8 | 1.0029 | 1.2504 | 1.5774 |

TABLE 8
Influence of Fault Resistance on Accuracy for LG Faults
(Actual FL 0.4 p.u. From Respective Terminals)

| | Fault | Error of Estimated FL (%) | | |
|---|---|---|---|---|
| | Res. | for type | | |
| Term. | (Ω) | AG | BG | CG |
| A | 0 | 0.0390 | 0.0944 | 0.4494 |
| | 1 | 0.0478 | 0.1003 | 0.4478 |
| | 50 | 0.4255 | 0.3640 | 0.2664 |
| | 150 | 0.9713 | 0.5523 | 0.3640 |
| | 200 | 1.1879 | 0.5777 | 0.6789 |
| B | 0 | 0.7513 | 0.7935 | 1.2493 |
| | 1 | 0.7376 | 0.8032 | 1.2517 |
| | 50 | 0.2129 | 1.1788 | 1.0885 |
| | 150 | 0.5285 | 1.4232 | 0.4862 |
| | 200 | 0.8038 | 1.5294 | 0.2633 |
| C | 0 | 0.9472 | 0.9792 | 1.3923 |
| | 1 | 0.9345 | 0.9851 | 1.3937 |
| | 50 | 0.4060 | 1.2774 | 1.2619 |
| | 150 | 0.3706 | 1.4690 | 0.6462 |
| | 200 | 0.6664 | 1.5334 | 0.3851 |

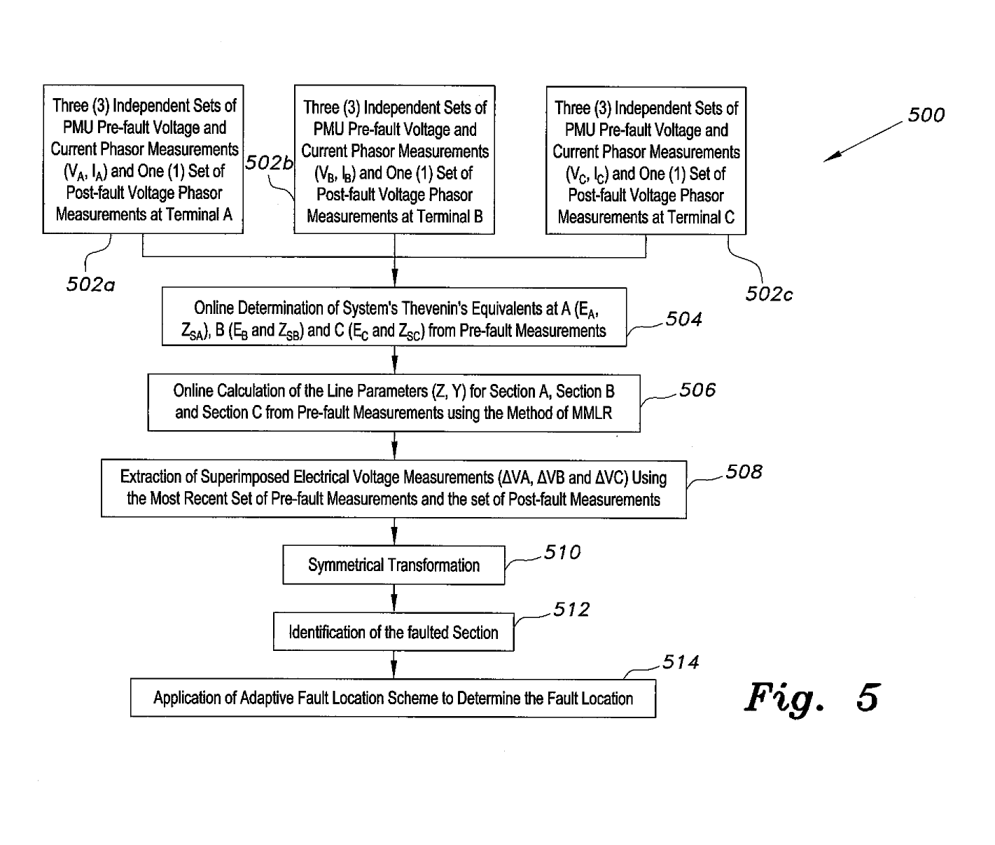

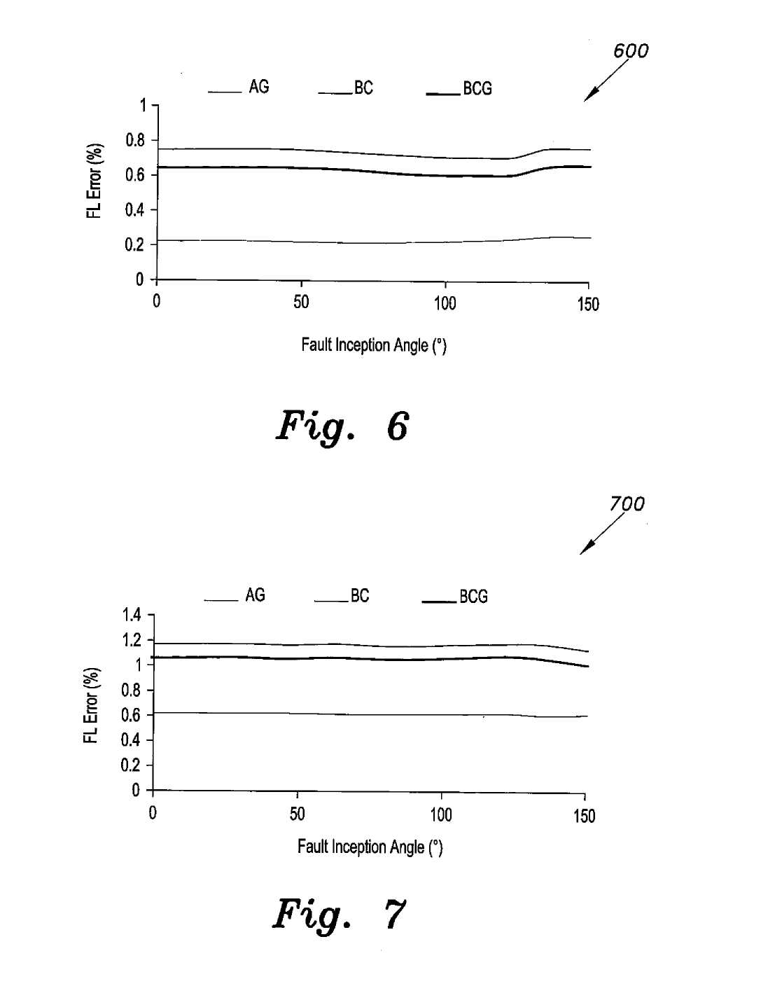

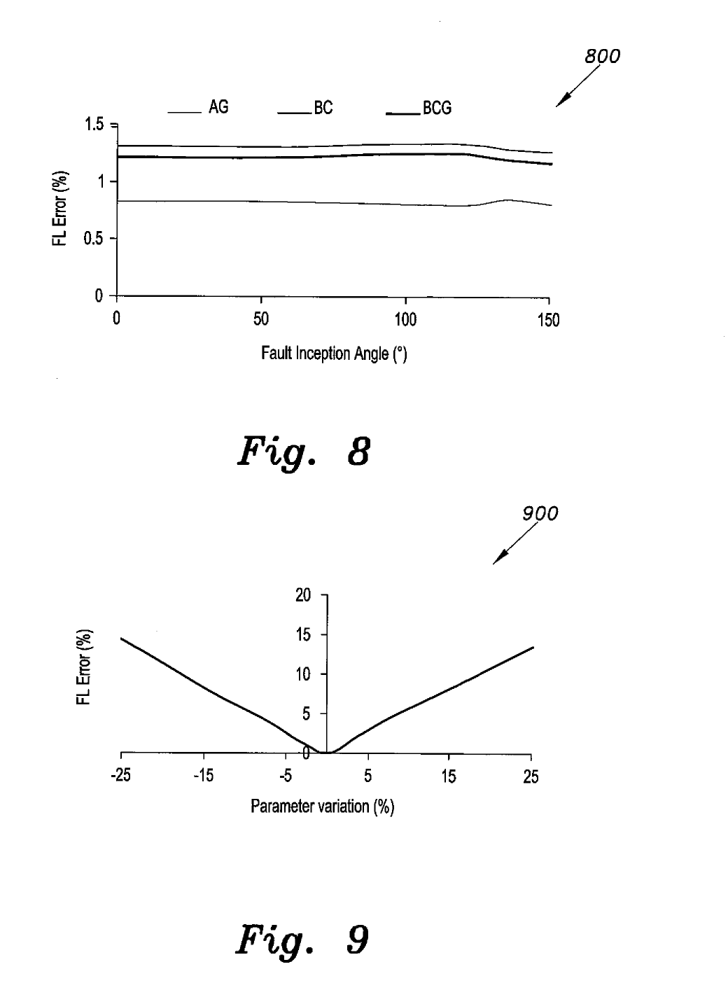

The effect of the variation of the fault inception angle (FIA) on the algorithm's accuracy for AG, BC and BCG faults is shown in Table 12, assuming that the fault occurs at a distance of 0.4 p.u. from terminals A, B and C, respectively. Fault inception angle is varied from 0 to 150°. It can be observed that the proposed algorithm is accurate and virtually independent of the fault inception angle. Plots 600, 700, and 800 of FIGS. 6 through 8, respectively, depict the effect of the variation of the fault inception angle on the algorithm's accuracy.

Table 13 shows the influence of the pre-fault loading on the algorithm's accuracy for AG, BC and BCG, faults assuming that these faults occur at 0.4 p.u. distance from terminals A, B and C, respectively. The pre-fault loading is varied from 0.5 to twice its base case value. It can be observed that the present method is reasonably accurate and virtually independent of the pre-fault loading.

TABLE 9
Influence of Fault Resistance on Accuracy for LL Faults
(Actual FL 0.4 p.u. From Respective Terminals)

| | Fault | Error of Estimated FL (%) | | |
|---|---|---|---|---|
| | Res. | for type | | |
| Term. | (Ω) | AB | BC | CA |
| A | 0 | 0.0014 | 0.4901 | 0.3593 |
| | 5 | 0.0018 | 0.5043 | 0.3372 |
| | 15 | 0.0076 | 0.5326 | 0.2925 |
| | 20 | 0.0098 | 0.5465 | 0.2698 |
| | 30 | 0.0128 | 0.5728 | 0.2236 |
| B | 0 | 0.6121 | 1.1116 | 1.0704 |
| | 5 | 0.6043 | 1.1425 | 1.0433 |
| | 15 | 0.5944 | 1.2001 | 0.9863 |
| | 20 | 0.5914 | 1.2263 | 0.9570 |
| | 30 | 0.5874 | 1.2728 | 0.8974 |
| C | 0 | 0.8813 | 1.2654 | 1.2343 |
| | 5 | 0.8072 | 1.2880 | 1.2104 |
| | 15 | 0.7876 | 1.3328 | 1.1606 |
| | 20 | 0.7796 | 1.3543 | 1.1348 |
| | 30 | 0.7663 | 1.3943 | 1.0817 |

TABLE 10
Influence of Fault Resistance on Accuracy for LLG Faults
(Actual FL 0.4 p.u. From Respective Terminals)

| | Fault | Error of Estimated FL (%) | | |
|---|---|---|---|---|
| | Res. | for type | | |
| Term. | (Ω) | ABG | BCG | CAG |
| A | 0 | 0.2002 | 0.4443 | 0.3789 |
| | 10 | 0.1912 | 0.4662 | 0.3822 |
| | 75 | 0.1524 | 0.5253 | 0.4494 |
| | 150 | 0.1260 | 0.5291 | 0.4577 |
| | 250 | 0.1065 | 0.5269 | 0.4537 |
| B | 0 | 0.7717 | 1.0212 | 1.0005 |
| | 10 | 0.7761 | 1.0631 | 1.0350 |
| | 75 | 0.7818 | 1.1665 | 1.1677 |
| | 150 | 0.7615 | 1.1708 | 1.1771 |
| | 250 | 0.7384 | 1.1650 | 1.1675 |
| C | 0 | 1.0091 | 1.2325 | 1.2158 |
| | 10 | 1.0402 | 1.2921 | 1.2667 |
| | 75 | 1.0566 | 1.3911 | 1.3983 |
| | 150 | 1.0321 | 1.3912 | 1.4051 |
| | 250 | 1.0079 | 1.3840 | 1.3952 |

TABLE 11
Influence of Fault Resistance on Accuracy for LLL Faults
(Actual FL 0.4 p.u. From Respective Terminals)

| | | Error of |
|---|---|---|
| | Fault | Estimated FL |
| Term. | Res. (Ω) | (%) |
| A | 0 | 0.3988 |
| | 5 | 0.3916 |
| | 15 | 0.3432 |
| | 20 | 0.3773 |
| | 30 | 0.3516 |
| B | 0 | 1.0100 |
| | 5 | 1.0403 |
| | 15 | 1.0969 |
| | 20 | 1.1220 |
| | 30 | 1.1658 |
| C | 0 | 1.1368 |
| | 5 | 1.1544 |
| | 15 | 1.1894 |
| | 20 | 1.2053 |
| | 30 | 1.2325 |

TABLE 12
Influence of Fault Inception Angle on Accuracy
(Actual FL 0.4 p.u. From Respective Terminals)

| | | Fault Type | | |
|---|---|---|---|---|
| | | AG | BC | BCG |
| | Fault | Error of | Error of | Error of |
| | Inception | Estim. | Estim. | Estim. |
| Term. | Angle (°) | FL (%) | FL (%) | FL (%) |
| A | 0 | 0.2232 | 0.7490 | 0.6460 |
| | 30 | 0.2225 | 0.7535 | 0.6509 |
| | 45 | 0.2241 | 0.7510 | 0.6483 |
| | 60 | 0.2206 | 0.7466 | 0.6431 |
| | 90 | 0.2233 | 0.7192 | 0.6151 |
| | 120 | 0.2400 | 0.7121 | 0.6110 |
| | 135 | 0.2604 | 0.7644 | 0.6575 |
| | 150 | 0.2604 | 0.7643 | 0.6662 |
| B | 0 | 0.6224 | 1.1722 | 1.0631 |
| | 30 | 0.6215 | 1.1778 | 1.0694 |
| | 45 | 0.6250 | 1.1690 | 1.0592 |
| | 60 | 0.6173 | 1.1739 | 1.0649 |
| | 90 | 0.6178 | 1.1634 | 1.0563 |
| | 120 | 0.6275 | 1.1859 | 1.0790 |
| | 135 | 0.6111 | 1.1766 | 1.0635 |
| | 150 | 0.6169 | 1.1390 | 1.0214 |
| C | 0 | 0.8240 | 1.3106 | 1.2190 |
| | 30 | 0.8241 | 1.3082 | 1.2160 |
| | 45 | 0.8260 | 1.3076 | 1.2158 |
| | 60 | 0.8253 | 1.3122 | 1.2212 |
| | 90 | 0.8217 | 1.3349 | 1.2474 |
| | 120 | 0.8041 | 1.3400 | 1.2512 |
| | 135 | 0.8493 | 1.2942 | 1.2053 |
| | 150 | 0.8079 | 1.2712 | 1.1733 |

TABLE 13
Influence of Pre-Fault Loading at Terminals A, B, and C on Accuracy
(Actual FL 0.4 p.u. From Respective Terminal)

| | Variation | Fault Type | | |
|---|---|---|---|---|
| | of Pre- | AG | BC | BCG |
| | fault | Error of | Error of | Error of |
| | Loading | Estim. | Estim. | Estim. |
| Term. | (%) | FL (%) | FL (%) | FL (%) |
| A | −50 | 0.2625 | 0.2696 | 0.1652 |
| | −20 | 0.0287 | 0.5580 | 0.4543 |
| | 20 | 0.4180 | 0.9402 | 0.8379 |
| | 50 | 0.7107 | 1.2280 | 1.1265 |
| | 100 | 1.1998 | 1.7099 | 1.6096 |
| B | −50 | 0.0741 | 0.6351 | 0.5250 |
| | −20 | 0.4025 | 0.9569 | 0.8474 |
| | 20 | 0.8429 | 1.3882 | 1.2795 |
| | 50 | 1.1750 | 1.7137 | 1.6054 |
| | 100 | 1.7313 | 2.2599 | 2.1522 |
| C | −50 | 0.2108 | 0.7078 | 0.6155 |
| | −20 | 0.5780 | 1.0692 | 0.9772 |
| | 20 | 1.0707 | 1.5525 | 1.4613 |
| | 50 | 1.4421 | 1.9166 | 1.8261 |
| | 100 | 2.0643 | 2.5268 | 2.4373 |

TABLE 14
INFLUENCE OF LINE PARAMETERS AND SYSTEM IMPEDANCE
VARIATION ON THE ALGORITHM'S ACCURACY

Fault Type

| | AG | BC | CAG | ABC |
|---|---|---|---|---|
| Parameter | Error of | Error of | Error of | Error of |
| Variation | Estim. | Estim. | Estim. | Estim. |
| (%) | FL (%) | FL (%) | FL (%) | FL (%) |
| −25 | 14.3714 | 13.9135 | 14.0662 | 14.1032 |
| −20 | 11.3209 | 10.8551 | 11.0108 | 11.0480 |
| −15 | 8.3392 | 7.8654 | 8.0242 | 8.0617 |
| −10 | 5.4232 | 4.9417 | 5.1034 | 5.1411 |
| −5 | 2.5700 | 2.0808 | 2.2455 | 2.2834 |
| 0 | 0.2232 | 0.7200 | 0.5523 | 0.5142 |
| 5 | 2.9593 | 3.4636 | 3.2930 | 3.2547 |
| 10 | 5.6412 | 6.1531 | 5.9795 | 5.9411 |
| 15 | 8.2717 | 8.7912 | 8.6146 | 8.5761 |
| 20 | 10.8537 | 11.3809 | 11.2012 | 11.1626 |
| 25 | 13.3900 | 13.9250 | 13.7421 | 13.7034 |

In the present adaptive fault location algorithm for three-terminal lines, system impedance and line parameters are determined online, and thus the effect of the surrounding environment and operation history on these parameters is nullified. System impedance and line parameters determined online from PMU synchronized measurements certainly reflect the system's practical operating conditions prior to and after the fault occurrence. In non-adaptive fault location algorithms, system impedance and line parameters are provided by the electric utility and assumed to be constant, regardless of the environmental and system operating conditions. Such assumption, however, is considered as a source of error that impacts the fault location accuracy. Investigating the effect of system impedance and line parameters uncertainty on fault location accuracy, assuming that they vary within ±25% from their practical values, results in Table 14, which shows the influence of the line parameters and system impedance variation on algorithm accuracy for AG, BC, CAG and ABC faults, assuming that these faults occur at 0.4 p.u. distance from terminal A. From the simulation results, one can easily observe that the effect of system impedance and parameters uncertainty on fault location can reach up to 14% if the parameters used in fault location vary 25% from the practical parameters. Plot 900 of FIG. 9 depicts the effect of the system impedance and line parameter variation on the algorithm's accuracy.

A fully adaptive fault location method for three-terminal lines using synchronized phasor measurements obtained by PMUs has been described in detail herein. The present method is capable of locating faults with high accuracy and does not require any data to be provided by the electric utility. Moreover, line parameters for each section of the line and Thevenin's equivalents of the system at each of the three terminals are determined online using three independent sets of pre-fault PMU measurements. This helps overcome degradation of system impedance and line parameter uncertainty. Additionally, the present method's accuracy is independent of fault type, fault location, fault resistance, fault inception angle, and pre-fault loading. In comparison with a non-adaptive algorithm for a three-terminal line, it has been observed that the effect of system impedance and parameters uncertainty on fault location can reach up to 14% if the parameters used in fault location vary 25% from the practical parameters.

It is to be understood that the present invention is not limited to the embodiments described above, but encompasses any and all embodiments within the scope of the following claims.

We claim:

1. A fully adaptive fault location method, comprising the steps of:
acquiring three independent sets of phasor measurement unit (PMU) pre-fault voltage and current phasor measurements (V_{A}, I_{A}) from a first terminal in a three-terminal power transmission network;
acquiring at least one set of PMU post-fault voltage phasor measurements from the first terminal;
acquiring three independent sets of phasor measurement unit (PMU) pre-fault voltage and current phasor measurements (V_{B}, I_{B}) from a second terminal in the three-terminal power transmission network;
acquiring at least one set of PMU post-fault voltage phasor measurements from the second terminal;
acquiring three independent sets of phasor measurement unit (PMU) pre-fault voltage and current phasor measurements (V_{C}, I_{C}) from a third terminal in the three-terminal power transmission network;
acquiring at least one set of PMU post-fault voltage phasor measurements from the third terminal;
determining online the power system network Thevenin equivalents (E_{A}, Z_{SA}) at the first terminal, (E_{B}, Z_{SB}) at the second terminal, and (E_{C}, Z_{SC}) at the third terminal based on the pre-fault measurements;
calculating online line impedance and admittance parameters (Z,Y) of the three-terminal power transmission network for a first section A that includes the first terminal, a second section B that includes the second terminal, and a third section C that includes the third terminal, the online calculations (Z,Y) being based on the pre-fault measurements using multiple measurements with linear regression (MMLR);
extracting superimposed electrical voltage measurements (ΔVA, ΔVB and ΔVC) using the most recent set of the pre-fault measurements for each of the first, second, and third terminals and the corresponding at least one set of PMU post-fault voltage phasor measurements for each of the first, second and third terminals, respectively;
obtaining positive, negative and zero sequence phasors using the superimposed electrical voltage measurements, the sequence phasors corresponding to a sequence network;
identifying which of sections A, B, and C is faulted using a steady-state π equivalent model of the three-terminal power transmission network, the steady-state π equivalent model being based on the sequence network and the Thevenin equivalents (E_{A}, Z_{SA}), (E_{B}, Z_{SB}), and (E_{C}, Z_{SC}), where E_{A}, E_{B}, and E_{C} correspond to section A, section B, and section C Thevenin equivalent voltage sources and Z_{SA}, Z_{SB}, and Z_{SC} are their respective Thevenin equivalent impedances; and
determining the fault-identified section's location using a total length L of the fault identified section and a voltage VM at a node M connecting the sections A, B, and C, the voltage VM being calculated as a function of the online line impedance and admittance parameters (Z,Y), and the superimposed voltages (ΔVA, ΔVB and ΔVC);
wherein the PMU measurements acquisitions are synchronized by a common temporal reference.

2. The fully adaptive fault location method according to claim 1, wherein the step of obtaining the positive, negative and zero sequence phasors further comprises the step of solving an equation characterized by the relation:
$$[ \begin{matrix}{X}_{1} \\ {X}_{2} \\ {X}_{0}\end{matrix} ] = \frac{1}{3} [ \begin{matrix}1 & {e}^{j 2 π / 3} & {e}^{j 4 π / 3} \\ 1 & {e}^{j 4 π / 3} & {e}^{j 2 π / 3} \\ 1 & 1 & 1\end{matrix} ] \cdot [ \begin{matrix}{X}_{a} \\ {X}_{b} \\ {X}_{c}\end{matrix} ]$$
wherein
$$[ \begin{matrix}{X}_{a} \\ {X}_{b} \\ {X}_{c}\end{matrix} ]$$
are phasors for three phases of the three terminal power transmission network;
and
wherein
$$[ \begin{matrix}{X}_{1} \\ {X}_{2} \\ {X}_{0}\end{matrix} ]$$
are the positive, negative, and zero sequence phasors.

3. The fully adaptive fault location method according to claim 1, further comprising the steps of:
formulating first, second, and third systems of equations representing the first, second and third sets of measurements for the sections A, B, and C, the systems of equations being characterized by the relations:
(VM)₁−ZA*(IA)₁−0.5*(VA)₁*ZA*YA−(VA)₁=0 (5)
(VM)₁−ZB*(IB)₁−0.5*(VB)₁*ZB*YB−(VB)₁=0 (6)
(VM)₁−ZC*(IC)₁−0.5*(VC)₁*ZC*YC−(VC)₁=0; (7)
and
(VM)₂−ZA*(IA)₂−0.5*(VA)₂*ZA*YA−(VA)₂=0 (8)
(VM)₂−ZB*(IB)₂−0.5*(VB)₂*ZB*YB−(VB)₂=0 (9)
(VM)₂−ZC*(IC)₂−0.5*(VC)₂*ZC*YC−(VC)₂=0 (10)
and
(VM)₃−ZA*(IA)₃−0.5*(VA)₃*ZA*YA−(VA)₃=0 (11)
(VM)₃−ZB*(IB)₃−0.5*(VB)₃*ZB*YB−(VB)₃=0 (12)
(VM)₃−ZC*(IC)₃−0.5*(VC)₃*ZC*YC−(VC)₃=0; (13)
and
formulating equation (5) as two real nonlinear equations characterized by the relations:
$$\begin{matrix}Re [ {( VM )}_{1} ] - Re [ ZA ] * Re [ {( IA )}_{1} ] + Im [ ZA ] * Im [ {( IA )}_{1} ] + 0.5 * Re [ {( V A )}_{1} ] * Im [ ZA ] * Im [ YA ] + 0.5 * Im [ {( V A )}_{1} ] * Im [ YA ] * Re [ ZA ] - Re [ {( V A )}_{1} ] = 0 & ( 14 ) \\ Im [ {( VM )}_{1} ] - Re [ ZA ] * Im [ {( IA )}_{1} ] - Im [ ZA ] * Re [ {( IA )}_{1} ] - 0.5 * Re [ {( V A )}_{1} ] * Im [ YA ] * Re [ ZA ] + 0.5 * Im [ {( V A )}_{1} ] * Im [ ZA ] * Im [ YA ] - Im [ {( V A )}_{1} ] = 0 ; & ( 15 )\end{matrix}$$
formulating equations (6) through (13) each as two real nonlinear equations characterized in the same manner as equations (14) and (15), thereby establishing a total of 18 real nonlinear equations; and
solving for Re[ZA], Im[ZA], Im[YA], Re[ZB], Im[ZB], Im[YB], Re[ZC], Im[ZC], Im[YC], Re[(VM)₁], Im[(VM)₁], Re[(VM)₂], Im[(VM)₂], Re[(VM)₃], Im[(VM)₃] utilizing the 18 real nonlinear equations.

4. The fully adaptive fault location method according to claim 3, wherein the VM calculation is further characterized by the relations:
$$\begin{matrix}VM = ( {I}_{3 \times 3} + ZA ( YSA + \frac{YA}{2} ) ) Δ V A & ( 16 ) \\ VM = ( {I}_{3 \times 3} + ZB ( YSB + \frac{YB}{2} ) ) Δ VB & ( 17 ) \\ VM = ( {I}_{3 \times 3} + ZC ( YSC + \frac{YC}{2} ) ) Δ VC . & ( 18 )\end{matrix}$$

5. The fully adaptive fault location method according to claim 4, wherein the identified section's fault location determination step further comprises the steps of:
performing a set of calculations characterized by the following relations when the identified section is section B:
VF=VM+ZB(1−k)IFM, (19)
where VF is a faulted point voltage of section B, and
$$VF = Δ VB [ 1 + ZBk ( YSB + \frac{YB}{2} k ) ] , \qquad ( 20 )$$
where ΔVB is a faulted bus voltage of section B;
solving for k based on equating equations (19) and (20) to obtain an equation characterized by the relation:
k=f(ΔVA,ΔVB,ΔVC)→ak²+bk+c=0; (21)
determining the coefficients a, b, and c from a set of equations characterized by the relations:
$$a = ZB \frac{YB}{2} Δ VB + ZB \frac{YA}{2} Δ V A + ZB \frac{YC}{2} Δ VC \\ b = ZBYSB Δ VB - ZB \frac{YA}{2} Δ V A - ZB \frac{YC}{2} Δ VC + ZB \frac{YB}{2} VM + ZBYSA Δ V A + ZBYSC Δ VC + ZB ( \frac{YA}{2} + \frac{YB}{2} + \frac{YC}{2} ) VM \\ c = Δ VB - VM - ZBYSA Δ V A - ZBYSC Δ VC - ZB ( \frac{YA}{2} + \frac{YB}{2} + \frac{YC}{2} ) VM , \qquad ( 22 )$$
where VM is obtained using one of equations (16) and equations (18); and
wherein the section B location determining step is further characterized by the relation,
l_{1B}=k×L_{B} (23)
where l_{1B} is the distance of the section B fault from a section B bus, and L_{B} is the total length of section B.

6. The fully adaptive fault location method according to claim 5, wherein the identified section's fault location determination step further comprises the steps of:
performing a set of calculations characterized by the following relations when the identified section is section A,
$$a = ZA \frac{YA}{2} Δ V A + ZA \frac{YB}{2} Δ VB + ZA \frac{YC}{2} Δ VC \\ b = ZAYSA Δ V A - ZA \frac{YB}{2} Δ VB - ZA \frac{YC}{2} Δ VC + ZA \frac{YA}{2} VM + ZAYSB Δ VB + ZAYSC Δ VC + ZA ( \frac{YA}{2} + \frac{YB}{2} + \frac{YC}{2} ) VM \\ c = Δ V A - VM - ZAYSB Δ VB - ZAYSC Δ VC - ZA ( \frac{YA}{2} + \frac{YB}{2} + \frac{YC}{2} ) VM , \qquad ( 24 )$$
where VM is obtained using one of equations (17) and equations (18); and
wherein the section A location determining step is further characterized by the relation,
l_{1A}=k×L_{A} (25)
where l_{1A} is the distance of the section A fault from a section A bus, and L_{A} is the total length of section A.

7. The fully adaptive fault location method according to claim 6, wherein the identified section's fault location determination step further comprises the steps of:
performing a set of calculations characterized by the following relations when the identified section is section C:
$$a = ZC \frac{YC}{2} Δ VC + ZC \frac{YA}{2} Δ V A + ZC \frac{YB}{2} Δ VB \\ b = ZCYSC Δ VC - ZC \frac{YA}{2} Δ V A - ZC \frac{YB}{2} Δ VB + ZC \frac{YC}{2} VM + ZCYSA Δ V A + ZCYSB Δ VB + ZC ( \frac{YA}{2 } + \frac{YB}{2} + \frac{YC}{2} ) VM \\ c = Δ VC - VM - ZCYSA Δ V A - ZCYSB Δ VB - ZC ( \frac{YA}{2} + \frac{YB}{2} + \frac{YC}{2} ) VM \qquad ( 26 )$$
where VM is obtained using one of equations (16) and (17); and
wherein the section C location determining step is further characterized by the relation,
l_{1C}=k×L_{C} (27)
where l_{1C} is the distance of the section C fault from a section C bus, and L_{C} is the total length of section C.
